(19) United States
(12) Patent Application Publication
(10) Pub. No.: US 2006/0245852 A1
(43) Pub. Date: Nov. 2, 2006

(54) Load lock apparatus, load lock section, substrate processing system and substrate processing method

(75) Inventor: Katsuhiko Iwabuchi, Tsuki-gun (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/390,259

(22) Filed: Mar. 28, 2006

(30) Foreign Application Priority Data
Mar. 30, 2005 (JP) 2005-099499

(51) Int. Cl. H01L 21/677

(52) U.S. Cl. 414/217

(57) ABSTRACT

A substrate processing system including a processing section for processing a substrate; a carry-in/out section for carrying in/out the substrate; and a load lock section provided between the processing section and the carry-in/out section, is characterized in that the load lock section includes a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate, that the second load lock apparatus includes a first cooling plate and a second cooling plate each for cooling the substrate supported on the supporting members, and that one of the first cooling plate and the second cooling plate is located on a front surface side of the substrate and another is located on a rear surface side of the substrate.

### BACKGROUND OF THE INVENTION

1. Field of the Invention

The present invention relates to a substrate processing system for processing an LCD substrate or the like, and to a load lock section and a load lock apparatus each for carrying in/out the substrate to a substrate processing section, and further to a substrate processing method.

2. Description of the Related Art

In a manufacturing process of, for example, an LCD substrate or the like, a so-called multi-chamber type processing system is used which includes a plurality of substrate processing apparatuses for performing predetermined processing for the substrate in a reduced-pressure atmosphere, such as etching, ashing, and so on (see Japanese Translated National Publication of Patent Application No. 2004-523880). Such a processing system includes a carrier room including a substrate carrier unit for carrying the substrate and a processing section having a plurality of substrate processing apparatuses provided around the carrier room. The substrate is carried in/out to/from each of the substrate processing apparatuses by a carrier arm of the substrate carrier unit.

The processing system further includes a carry-in/out section including a cassette station and so on, and a load lock section provided between the carry-in/out section and the processing section. The load lock section is provided for the purpose of keeping a vacuum in the processing section to prevent the processing section from opening to the carry-in/out section side which is at an atmospheric pressure, and is located, for example, adjacent to the carrier room. In this configuration, the substrate carried to the carry-in/out section is first housed in the load lock section via a carry-in/out port provided on the carry-in/out section side of the load lock section. When the pressure in the load lock section is then reduced into vacuum and the carry-in/out port provided on the processing section side of the load lock section is opened so that the load lock section communicates with the carrier room, the substrate is carried out of the load lock section by the carrier arm of the substrate carrier unit and carried to each of the substrate processing apparatuses. The substrate processed in each of the substrate processing apparatuses in the processing section is taken out by the carrier arm of the substrate carrier unit and housed in the load lock section via the carry-in/out port on the carry-in/out section side of the load lock section. When the pressure in the load lock chamber is returned to the atmospheric pressure by pressurization, the carry-in/out port on the carry-in/out section side of the load lock section is opened, so that the substrate is returned to the carry-in/out section.

As the load lock section, there is known one which includes a heater for pre-heating the substrate in the load lock section. Further, a load lock section is proposed which includes a heating plate and a cooling plate, so that when the substrate is carried from the carry-in/out section into the processing section, the substrate can be heated by the heating plate in the load lock section, and when the substrate is carried out of the processing section into the carry-in/out section, the substrate can be cooled by the cooling plate in the load lock section (see Japanese Patent Application Laid-open No. 2001-239144).

### SUMMARY OF THE INVENTION

However, it is difficult to efficiently heat or cool the substrate in the load lock section of the conventional processing system, and therefore it has been desired to efficiently heat or cool the substrate. Further, the substrate has sometimes warped due to the thermal stress. In that case, there have been concerns about disadvantages, such as breakage occurring in the substrate, the substrate being unstably held by the carrier arm at the time of carriage, and the substrate being not preferably housed in the cassette.

It is an object of the present invention to provide a load lock apparatus capable preferably heating or cooling a substrate, a load lock section including the load lock apparatus, a substrate processing system and a substrate processing method.

To solve the above problem, a load lock apparatus of the present invention is a load lock apparatus including a carry-in port provided on a side of a carry-in/out section for carrying in/out a substrate, a carry-out port provided on a side of a processing section for processing the substrate, and supporting members for supporting the substrate, the apparatus including: a first heating plate and a second heating plate each for heating the substrate supported on the supporting members, wherein one of the first heating plate and the second heating plate is located on a front surface side of the substrate and another is located on a rear surface side of the substrate. According to the above configuration, heating the substrate from both surfaces by the first heating plate and the second heating plate enables efficient heating of the substrate and suppression of a temperature difference between both surfaces to prevent deformation of the substrate.

In this load lock apparatus, the substrate may be substantially horizontally supported on the supporting members. Further, the first heating plate and/or the second heating plate may be capable of being relatively brought close to or away from the substrate.

Another load lock apparatus of the present invention is a load lock apparatus including a carry-out port provided on a side of a carry-in/out section for carrying in/out a substrate, a carry-in port provided on a side of a processing section for processing the substrate, and supporting members for supporting the substrate, the apparatus including: a first cooling plate and a second cooling plate each for cooling the substrate supported on the supporting members, wherein one of the first cooling plate and the second cooling plate is located on a front surface side of the substrate and another is located on a rear surface side of the substrate. According to the above configuration, cooling the substrate from both surfaces by the first cooling plate and the second cooling plate enables efficient cooling of the substrate and suppression of a temperature difference between both surfaces to prevent deformation of the substrate.

The substrate may be substantially horizontally supported on the supporting members. The first cooling plate and/or the second cooling plate may be capable of being relatively brought close to or away from the substrate.

Further, a load lock section of the present invention is a load lock section including a first load lock apparatus including a carry-in port provided on a side of a carry-in/out section for carrying in/out a substrate, a carry-out port provided on a side of a processing section for processing the substrate, and supporting members for supporting the substrate; and a second load lock apparatus including a carry-out port provided on the carry-in/out section side, a carry-in port provided on the processing section side, and supporting members for supporting the substrate, wherein the first load lock apparatus includes a first heating plate and a second heating plate each for heating the substrate supported on the supporting members, wherein one of the first heating plate and the second heating plate is located on a front surface side of the substrate and another is located on a rear surface side of the substrate, wherein the second load lock apparatus includes a first cooling plate and a second cooling plate each for cooling the substrate supported on the supporting members, and wherein one of the first cooling plate and the second cooling plate is located on the front surface side of the substrate and another is located on the rear surface side of the substrate. In the load lock section, the first load lock apparatus and the second load lock apparatus may be stacked one on the other.

Further, a substrate processing system of the present invention is a substrate processing system including a processing section for processing a substrate; a carry-in/out section for carrying in/out the substrate; and a load lock section provided between the processing section and the carry-in/out section, wherein the load lock section includes a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate, wherein the first load lock apparatus includes a first heating plate and a second heating plate each for heating the substrate supported on the supporting members, wherein one of the first heating plate and the second heating plate is located on a front surface side of the substrate and another is located on a rear surface side of the substrate, and wherein the processing section includes a carrier unit for carrying the substrate between a substrate processing apparatus for processing the substrate and the load lock section.

Further, another substrate processing system of the present invention is a substrate processing system including a processing section for processing a substrate; a carry-in/out section for carrying in/out the substrate; and a load lock section provided between the processing section and the carry-in/out section, wherein the load lock section includes a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate, wherein the second load lock apparatus includes a first cooling plate and a second cooling plate each for cooling the substrate supported on the supporting members, wherein one of the first cooling plate and the second cooling plate is located on a front surface side of the substrate and another is located on a rear surface side of the substrate, and wherein the processing section includes a carrier unit for carrying the substrate between a substrate processing apparatus for processing the substrate and the load lock section.

Further, still another substrate processing system is a substrate processing system including a processing section for processing a substrate; a carry-in/out section for carrying in/out the substrate; and a load lock section provided between the processing section and the carry-in/out section, wherein the load lock section includes a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate, wherein the first load lock apparatus includes a first heating plate and a second heating plate each for heating the substrate supported on the supporting members, wherein one of the first heating plate and the second heating plate is located on a front surface side of the substrate and another is located on a rear surface side of the substrate, wherein the second load lock apparatus includes a first cooling plate and a second heating plate each for cooling the substrate supported on the supporting members, wherein one of the first cooling plate and the second cooling plate is located on the front surface side of the substrate and another is located on the rear surface side of the substrate, and wherein the processing section includes a carrier unit for carrying the substrate between a substrate processing apparatus for processing the substrate and the load lock section.

Further, a processing method of the present invention is a substrate processing method of carrying a substrate from a carry-in/out section into a processing section via a first load lock apparatus provided in a load lock section, processing the substrate in the processing section, and carrying the substrate out of the processing section into the carry-in/out section via a second load lock apparatus provided in the load lock section, the method including the steps of: opening a carry-in port provided on the carry in/our section side of the first load lock apparatus with a carry-out port provided on the processing section side of the first load lock apparatus kept closed; carrying the substrate into the first load lock apparatus via the carry-in port of the first load lock apparatus, housing the substrate between a first heating plate and a second heating plate provided in the first load lock apparatus, and closing the carry-in port of the first load lock apparatus; heating the substrate housed in the first load lock apparatus from both surfaces by the first heating plate and the second heating plate; and opening the carry-out port of the first load lock apparatus with the carry-in port of the first load lock apparatus kept closed, and carrying the substrate into the processing section via the carry-out port of the first load lock apparatus.

In this processing method, it is also possible that a pressure in the processing section is reduced below a pressure in the carry-in/out section, that after the substrate is carried into the first load lock apparatus, the carry-in port of the first load lock apparatus is closed to bring an inside of the first load lock apparatus into a hermetically closed state; and that a pressure in the first load lock apparatus is reduced to a predetermined pressure, and the carry-out port of the first load lock apparatus is then opened to carry the substrate out of the first load lock apparatus to the processing section.

Further, this processing method may further including the steps of: opening a carry-in port provided on the processing section side of the second load lock apparatus with a carry-out port provided on the carry-in/out section side of the second load lock apparatus kept closed; carrying the substrate into the second load lock apparatus via the carry-in port of the second load lock apparatus, housing the substrate between a first cooling plate and a second cooling plate provided in the second load lock apparatus, and closing the carry-in port of the second load lock apparatus; cooling the substrate housed in the second load lock apparatus from both surfaces by the first cooling plate and the second cooling plate; and opening the carry-out port of the second load lock apparatus with the carry-in port of the second load lock apparatus kept closed, and carrying out the substrate to the carry-in/out section via the carry-out port of the second load lock apparatus. In this case, it is also possible that a pressure in the processing section is reduced below a pressure in the carry-in/out section, that after the substrate is carried into the second load lock apparatus, the carry-in port of the second load lock apparatus is closed to bring an inside of the second load lock apparatus into a hermetically closed state, and that a pressure in the second load lock apparatus is increased to a predetermined pressure, and the carry-out port of the second load lock apparatus is then opened to carry the substrate out of the second load lock apparatus to the carry-in/out section.

Further, another processing method of the present invention is a substrate processing method of carrying a substrate from a carry-in/out section into a processing section via a first load lock apparatus provided in a load lock section, processing the substrate in the processing section, and carrying the substrate out of the processing section into the carry-in/out section via a second load lock apparatus provided in the load lock section, the method including the steps of: at the time of carrying the substrate from the processing section to the carry-in/out section, opening a carry-in port provided on the processing section side of the second load lock apparatus with a carry-out port provided on the carry-in/out section side of the second load lock apparatus kept closed; carrying the substrate into the second load lock apparatus via the carry-in port of the second load lock apparatus, housing the substrate between a first cooling plate and a second cooling plate provided in the second load lock apparatus, and closing the carry-in port of the second load lock apparatus; cooling the substrate housed in the second load lock apparatus from both surfaces by the first cooling plate and the second cooling plate; and opening the carry-out port of the second load lock apparatus with the carry-in port of the second load lock apparatus kept closed, and carrying out the substrate to the carry-in/out section via the carry-out port of the second load lock apparatus.

In this processing method, it is also possible that a pressure in the processing section is reduced below a pressure in the carry-in/out section, that after the substrate is carried into the second load lock apparatus, the carry-in port of the second load lock apparatus is closed to bring an inside of the second load lock apparatus into a hermetically closed state; and that a pressure in the second load lock apparatus is increased to a predetermined pressure, and the carry-out port of the second load lock apparatus is then opened to carry the substrate out of the second load lock apparatus to the carry-in/out section.

### BRIEF DESCRIPTION OF THE DRAWINGS

FIG. 1 is a schematic plan view illustrating a configuration of a processing system;

FIG. 2 is a schematic side view illustrating the configuration of the processing system; and

FIG. 3 is a schematic longitudinal sectional view of a load lock apparatus.

### DETAILED DESCRIPTION OF THE PREFERRED EMBODIMENT

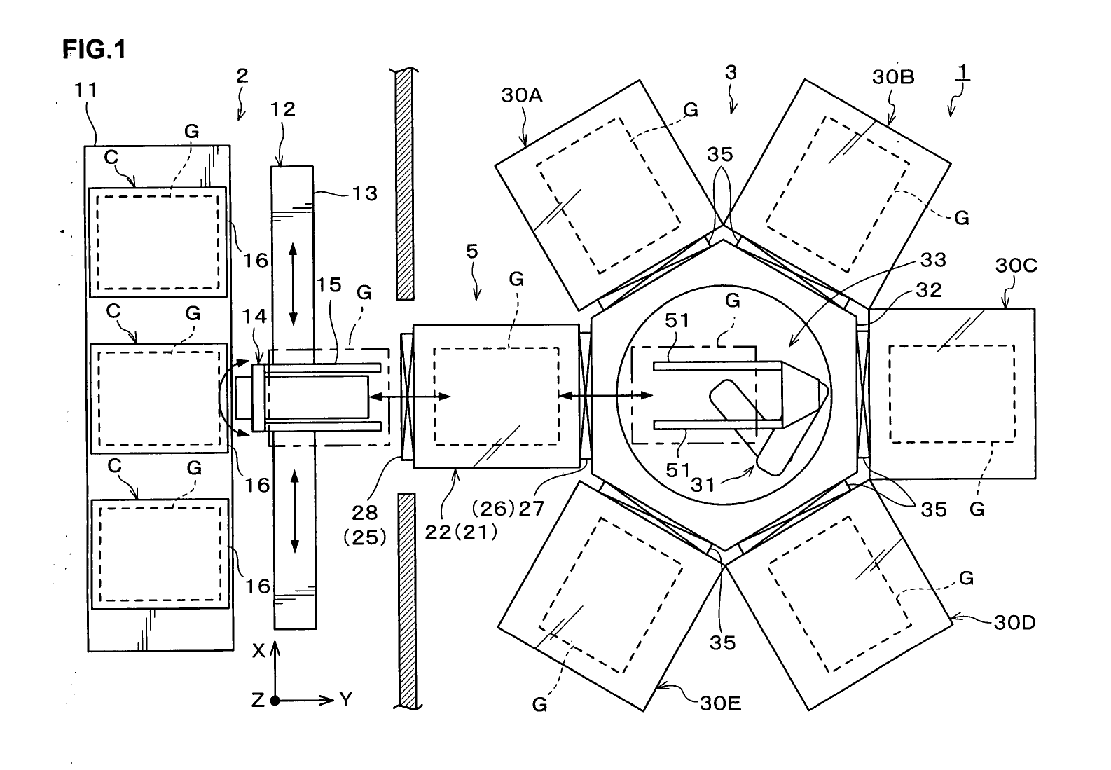

Hereinafter, a preferred embodiment of the present invention will be described based on a processing system which embodies processes of forming a thin film by plasma CVD (Chemical Vapor Deposition) processing for a glass substrate G for LCD (Liquid Crystal Display) as an example of a substrate. FIG. 1 is a plan view showing a schematic configuration of a processing system 1 according to the embodiment of the present invention. The processing system 1 shown in FIG. 1 is a so-called multi-chamber type processing system which includes a carry-in/out section 2 for carrying in/out the substrate G to/from the outside of the processing system 1; a processing section 3 for performing CVD processing for the substrate G; and a load lock section 5 arranged between the carry-in/out section 2 and the processing section 3.

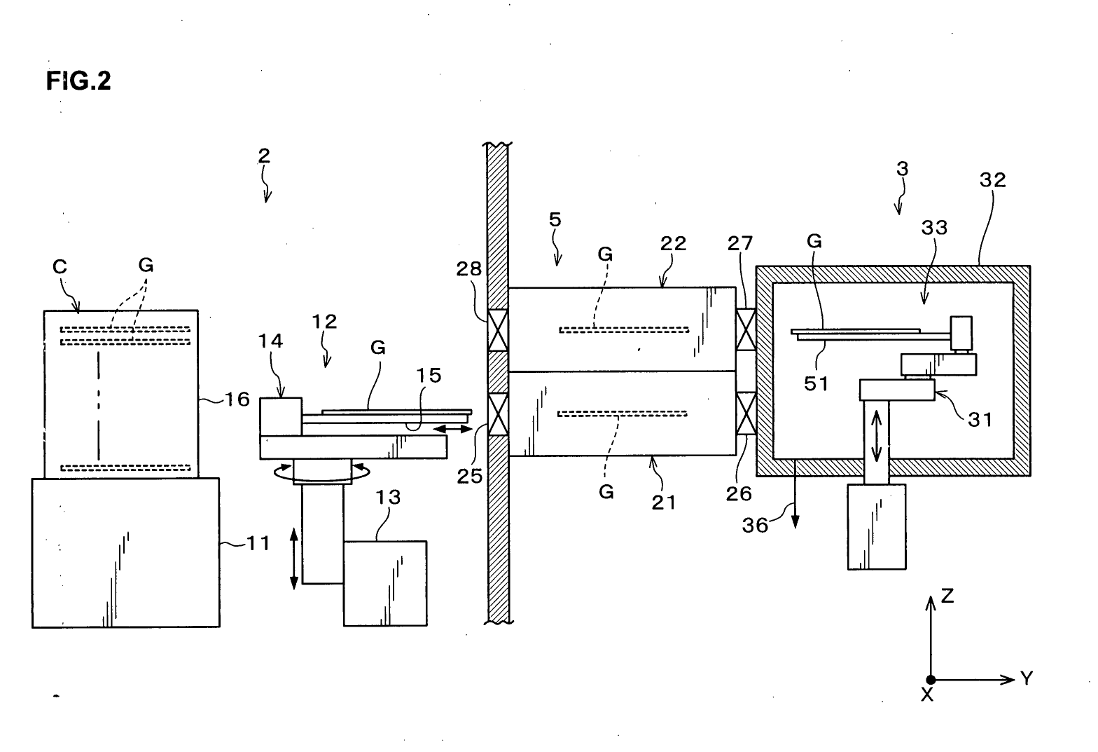

In the carry-in/out section 2, a mounting table 11 on which cassettes C housing a plurality of substrates G are mounted and a first carrier unit 12 for carrying the substrate G are provided. On the mounting table 11, a plurality of the cassettes C are arranged along an X-axis direction that is a substantially horizontal direction in FIG. 1. As shown in FIG. 2, a plurality of substantially rectangular substrates G in a thin plate shape are housed in each of the cassettes C on the mounting table 11 such that they are arranged one above the other, each in a substantially horizontal position.

The carrier unit 12 is provided at the rear (the right side in FIG. 1) of the mounting table 11 in a Y-axis direction in the horizontal direction. The carrier unit 12 further includes a rail 13 extending along the X-axis direction and a carrier mechanism 14 movable in the horizontal direction along the rail 13. The carrier mechanism 14 includes a carrier arm 15 for holding one substrate G in the substantially horizontal direction, and the carrier arm 15 is configured to be able to expand and contract in a Z-axis direction (the vertical direction) and rotatable within a substantially horizontal plane. In other words, the carrier unit 12 is configured such that the carrier arm 15 can access an opening 16 provided in the front surface of each cassette C on the mounting table 11 so as to take the substrates G one by one. Further, the carrier arm 15 can access the load lock section 5 provided on the side (at the rear of the carrier unit 12 in the Y-axis direction) opposed to the mounting table 11 across the carrier unit 12 so as to carry-in and carry-out the substrates G one by one to/from the load lock section 5.

As shown in FIG. 2, the load lock section 5 is composed of a pair of load lock apparatuses, that is, a first load lock apparatus 21 and a second load lock apparatus 22. The first load lock apparatus 21 and the second load lock apparatus 22 are provided stacked one on the other such that the second load lock apparatus 22 is stacked on the first load lock apparatus 21 in the illustrated example. Further, a gave valve 25, which opens/closes a later-described carry-in port 63, of the first load lock apparatus 21 is provided on the front side (the left side in FIG. 2) of the first load lock apparatus 21 in the Y-axis direction, and a gave valve 26, which opens/closes a later-described carry-out port 64, of the first load lock apparatus 21 is provided on the rear side of the first load lock apparatus 21 in the Y-axis direction. A gave valve 27, which opens/closes a later-described carry-in port 103, of the second load lock apparatus 22 is provided on the rear side of the second load lock apparatus 22 in the Y-axis direction, and a gave valve 28, which opens/closes a later-described carry-out port 104, of the second load lock apparatus 22 is provided on the front side of the second load lock apparatus 22 in the Y-axis direction. In this configuration, closing the gate valves 25 and 28 allows the atmosphere in the carry-in/out section 2 to be shut off from the atmospheres in the load lock apparatuses 21 and 22 respectively. Further, closing the gate valves 26 and 27 allows the atmosphere in the processing section 3 to be shut off from the atmospheres in the load lock apparatuses 21 and 22 respectively. Note that the substrate G is carried from the carry-in/out section 2 into the processing section 3 via the first load lock apparatus 21 at the lower tier, and the substrate G after processed in the processing section 3 is carried out to the carry-in/out section 2 via the second load lock apparatus 22 at the upper tier. This arrangement can prevent particles from adhering to the processed substrate G. The structure of each of the load lock apparatuses 21 and 22 will be described later in detail.

As shown in FIG. 1, the processing section 3 includes a plurality of, for example, five substrate processing apparatuses 30A to 30E each housing the substrate G and performing plasma CVD processing for it, and a second carrier unit 31 for carrying the substrate G between load lock section 5 and each of the substrate processing apparatuses 30A to 30E. The second carrier unit 31 is stored in a carrier room 33 provided in a chamber 32 having a hermetically closed structure. The chamber 32 is provided at the rear of the load lock section 5 in the Y-axis direction. Further, the load lock section 5 and the substrate processing apparatuses 30A to 30E are arranged in a manner to surround the periphery of the chamber 32.

Between the carrier room 33 and the load lock apparatuses 21 and 22, the above-described gate valves 26 and 27 are provided respectively, so that the gate valves 26 and 27 can shut off the atmosphere in the carrier room 33 from the atmospheres in the load lock apparatuses 21 and 22 respectively. Between the carrier room 33 and the substrate processing apparatuses 30A to 30E, gate valves 35 are provided respectively, so that the gate valves 35 can hermetically closes openings of the substrate processing apparatuses 30A to 30E to shut off the atmosphere in the carrier room 33 from the atmospheres in the substrate processing apparatuses 30A to 30E respectively. Further, as shown in FIG. 2, an exhaust path 36 is provided for forcibly evacuates the carrier room 33 to reduce the pressure therein. At the time of processing in the processing system 1, the atmospheres in the carrier room 33 of the processing section 3 and the substrate processing apparatuses 30A to 30E are reduced in pressure to be lower than that in the carry-in/out section 2, for example, into a vacuum state.

The second carrier unit 31 includes, for example, an articulated carrier arm 51. The carrier arm 51 is configured to be able to substantially horizontally hold one substrate G, and expand and contract in the Z-axis direction and rotatable within a substantially horizontal plane. In other words, the second carrier unit 31 is configured such that the carrier arm 51 can access the load lock apparatuses 21 and 22 and the substrate processing apparatuses 30A to 30E via the gate valves 26, 27, and 35 so as to carry-in or carry-out the substrates G one by one to/from them.

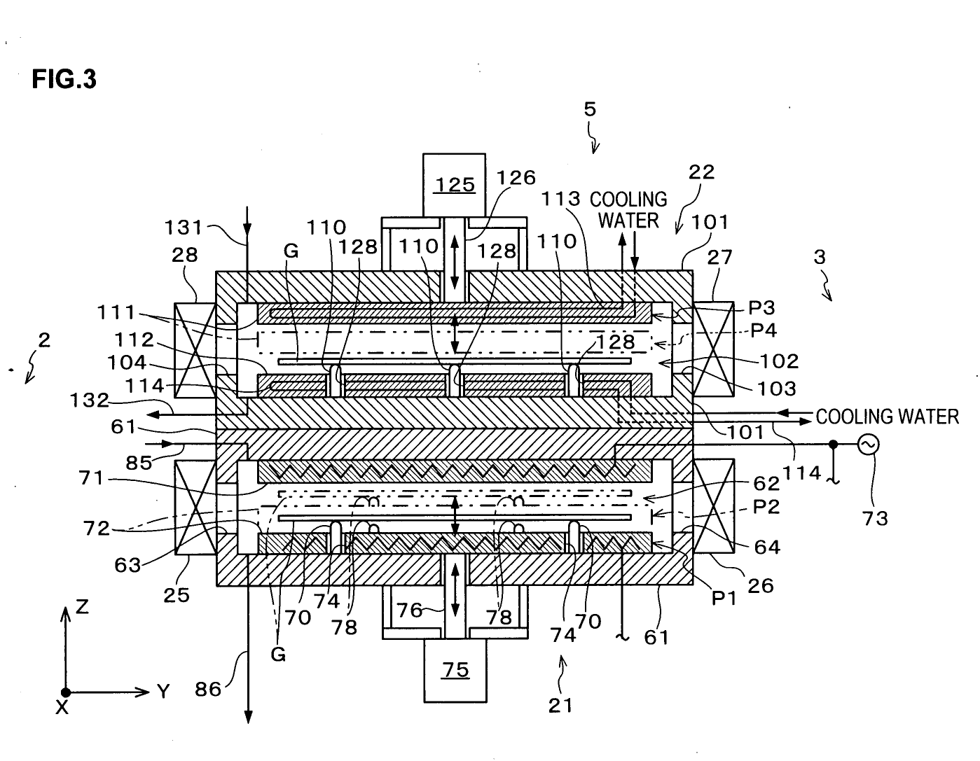

Next, the configuration of the aforementioned first load lock apparatus 21 will be described in detail. As shown in FIG. 3, the first load lock apparatus 21 includes a chamber 61 having a hermetically closed structure. The inside of the chamber 61 forms a load lock chamber 62 for housing the substrate G.

On the carry-in/out section 2 side, that is, on the front side in the Y-axis direction of the chamber 61, the carry-in port 63 is provided for carrying the substrate G into the load lock chamber 62. The carry-in port 63 is provided with the above-described gate valve 25 so that the carry-in port 63 can be hermetically closed by the gate valve 25. On the processing section 3 side, that is, on the rear side in the Y-axis direction of the chamber 61, the carry-out port 64 is provided for carrying the substrate G out of the load lock chamber 62. The carry-out port 64 is provided with the above-described gate valve 26 so that the carry-out port 64 can be hermetically closed by the gate valve 26.

In the load lock chamber 62, a plurality of holding members 70 are provided for supporting the substrate G. Each of the holding members 70 forms a substantially rod shape and is provided in a manner to project upward from the bottom of the chamber 61 so that the lower surface of the substrate G is mounted on the top end portions of the holding members 70, whereby the holding members 70 substantially horizontally support the substrate G.

Further, an upper surface heating plate 71 as a first heating plate for heating the substrate G supported on the holding members 70 and a lower surface heating plate 72 as a second heating plate are provided in the load lock chamber 62. Each of the upper surface heating plate 71 and the lower surface heating plate 72 is connected to an AC power source 73 and can be raised in temperature by a power fed from the AC power source 73.

The upper surface heating plate 71 forms a substantially rectangular thick plate, and is substantially horizontally provided along the ceiling of the chamber 61, placed on the upper surface (for example, the front surface on which devices are to be formed) side of the substrate G supported on the holding members 70, and secured to the chamber 61. Further, the upper surface heating plate 71 is opposed to the upper surface of the substrate G supported on the holding members 70 in a position substantially parallel to the upper surface. It should be noted that the lower surface of the upper surface heating plate 71 has an area larger than that of the upper surface of the substrate G so that it can heat the upper surface of the substrate G in a manner to cover the entire upper surface.

The lower surface heating plate 72 forms a substantially rectangular thick plate, and is substantially horizontally provided along the bottom of the chamber 61, placed on the lower surface (for example, the rear surface on which no device is to be formed) side of the substrate G supported on the holding members 70. The above-described holding members 70 are arranged within a plurality of holes 74 formed in the lower surface heating plate 72 respectively; The lower surface heating plate 72 is opposed to the lower surface of the substrate G held on the holding members 70 in a position substantially parallel to the lower surface.

The lower surface heating plate 72 is configured to be able to vertically raised and lowered so that it can approach and separate from the upper surface heating plate 71. For example, as shown in FIG. 3, a cylinder 75 is provided below the chamber 61 as a raising and lowering mechanism, and a rod 76 connected to the cylinder 75 is provided in a manner to vertically penetrate the bottom of the chamber 61. The lower surface heating plate 72 is attached to the lower end portion of the rod 76. Driving of the cylinder 75 raises and lowers the rod 76 in the Z-axis direction, whereby the lower surface heating plate 72 is raised and lowered integrally with the rod 76 with the holes 74 moving along the respective holding members 70.

Further, the upper surface of the lower surface heating plate 72 is provided with a plurality of supporting members 78 for supporting the substrate G at the time of heating. When the lower surface heating plate 72 is lowered to a waiting position P1, the supporting members 78 are located at positions lower than the top end portions of the holding members 70. Therefore, even if the substrate G is held on the holding members 70, the supporting members 78 never touch the substrate G. On the other hand, the lower surface heating plate 72 can be raised from the waiting position P1 to move the supporting members 78 to positions upper than the top end portions of the holding members 70. In other words, the substrate G held on the holding members 70 can be lifted by the supporting members 78, so that the substrate G is being supported on the supporting members 78. The supporting members 78 are configured to substantially horizontally support the substrate G by mounting the lower surface of the substrate G on the top end portions of the supporting members 78. Between the lower surface of the substrate G supported on the supporting members 78 and the upper surface of the lower surface heating plate 72, a clearance with a substantially uniform width is formed such that the substrate G and the lower surface heating plate 72 are arranged close to each other. At the time of heating the substrate G, the lower surface heating plate 72 is raised to a heating processing position P2, in which state the substrate G is supported on the plurality of supporting members 78. Further, the substrate G supported on the supporting members 78 and the above-described upper surface heating plate 71 are close to each other, such that a clearance with a substantially uniform width is formed between the substrate G supported on the supporting members 78 and the lower surface of the above-described upper surface heating plate 71. In other words, the upper surface heating plate 71 and the lower surface heating plate 72 are configured so that they can be respectively brought close to and away from the substrate G housed between them. It should be noted that the upper surface of the lower surface heating plate 72 has an area larger than that of the lower surface of the substrate G so that it can heat the lower surface of the substrate G in a manner to cover the entire lower surface.

The lower surface heating plate 72 configured to be raised and lowered with respect to the chamber 61 in the above manner makes it possible that at the time of passing the substrate G to the holding members 70, the lower surface heating plate 72 is lowered to the waiting position P1 to enable easy passing, and that at the time of heating the substrate G, the lower surface heating plate 72 is raised to the heating processing position P2 to enable efficient heating of the substrate G. Further, this configuration allows the cylinder 75 to be placed below the chamber 61 so as to reduce more space than in the case in which the upper surface heating plate 71 can be raised and lowered with respect to the chamber 61. More specifically, when the upper surface heating plate 71 is made such that it can be raised and lowered, a raising and lowering mechanism will be located between the second load lock apparatus 22 at the upper tier and the first load lock apparatus 21 at the lower tier, resulting in a large height between the carry-in port 63 and the carry-out port 64 of the first load lock apparatus 21 and the later-described carry-in port 103 and carry-out port 104 of the second load lock apparatus 22. In contrast, the above-described lower surface heating plate 72 never presents such a disadvantage but allows the height between them to be smaller. This can accordingly decrease the range of the vertical movement of the carrier units 12 and 31 and enhance the efficiency of carrying the substrate G Further, a gas supply path 85 for supplying an inert gas such as N₂ (nitrogen) gas, He (helium) gas or the like into the load lock chamber 62 and an exhaust path 86 for forcibly evacuating the load lock chamber 62 are connected to the chamber 62. In other words, the gas supply from the gas supply path 85 and the forcible evacuation through the exhaust path 86 enable adjustment of the pressure in the load lock chamber 62.

Next, the configuration of the aforementioned second load lock apparatus 22 will be described in detail. As shown in FIG. 3, the second load lock apparatus 22 includes a chamber 101 having a hermetically closed structure. In the illustrated example, the chamber 101 is mounted on the top surface of the chamber 61 of the first load lock apparatus 21 at the lower tier. The inside of the chamber 101 forms a load lock chamber 102 for housing the substrate G.

On the processing section 3 side, that is, on the rear side in the Y-axis direction of the chamber 101, the carry-in port 103 is provided for carrying the substrate G into the load lock chamber 102. The carry-in port 103 is provided with the above-described gate valve 27 so that the carry-in port 103 can be hermetically closed by the gate valve 27. On the carry-in/out section 2 side, that is, on the front side in the Y-axis direction of the chamber 101, the carry-out port 104 is provided for carrying the substrate G out of the load lock chamber 102. The carry-out port 104 is provided with the above-described gate valve 28 so that the carry-out port 104 can be hermetically closed by the gate valve 28.

In the load lock chamber 102, a plurality of supporting members 110 are provided for holding the substrate G. Each of the holding members 110 forms a substantially rod shape and is provided in a manner to project upward from the bottom of the chamber 101 so that the lower surface of the substrate G is mounted on the top end portions of the supporting members 110, whereby the holding members 110 substantially horizontally support the substrate G.

Further, an upper surface cooling plate 111 as a first cooling plate for cooling the substrate G and a lower surface cooling plate 112 as a second cooling plate are provided in the load lock chamber 102. The upper surface cooling plate 111 and the lower surface cooling plate 112 incorporate cooling water convey pipes 113 and 114 for conveying a cooling water respectively, so that the cold heat of the cooling water flowing through the cooling water convey pipes 113 and 114 cools the upper surface cooling plate 111 and the lower surface cooling plate 112.

The upper surface cooling plate 111 forms a substantially rectangular thick plate, and is substantially horizontally provided along the ceiling of the chamber 101, placed on the upper surface (for example, the front surface on which devices are to be formed) side of the substrate G supported on the supporting members 110. Further, the upper surface cooling plate 111 is opposed to the upper surface of the substrate G supported on the supporting members 110 in a position substantially parallel to the upper surface.

The upper surface cooling plate 111 is configured to be able to vertically raised and lowered so that it can approach and separate from the substrate G supported on the supporting members 110. For example, as shown in FIG. 3, a cylinder 125 is provided above the chamber 101 as a raising and lowering mechanism, and a rod 126 connected to the cylinder 125 is provided in a manner to vertically penetrate the ceiling of the chamber 101. The upper surface cooling plate 111 is attached to the lower end portion of the rod 126. Driving of the cylinder 125 raises and lowers the rod 126 in the Z-axis direction, whereby the upper surface cooling plate 111 is raised and lowered integrally with the rod 126. The upper surface cooling plate 111 moves, for example, to a waiting position P3 at an upper position away from the substrate G supported on the supporting members 110 and to a cooling processing position P4 at a lower position close to the substrate G It should be noted that the lower surface of the upper surface cooling plate 111 has an area larger than that of the upper surface of the substrate G so that it can cool the upper surface of the substrate G supported on the supporting members 110 in a manner to cover the entire upper surface.

The upper surface cooling plate 111 configured to be raised and lowered with respect to the chamber 101 in the above manner makes it possible that at the time of passing the substrate G to the supporting members 110, the upper surface cooling plate 111 is raised to the waiting position P3 to enable easy passing, and that at the time of cooling the substrate G, the upper surface cooling plate 111 is lowered to the cooling processing position P4 to enable efficient cooling of the substrate G. Further, this configuration allows the cylinder 125 to be placed above the chamber 101 so as to reduce more space than in the case in which the lower surface cooling plate 112 can be raised and lowered with respect to the chamber 101. More specifically, when the lower surface cooling plate 112 is made such that it can be raised and lowered, a raising and lowering mechanism will be located between the second load lock apparatus 22 at the upper tier and the first load lock apparatus 21 at the lower tier, resulting in a large height between the above-described carry-in port 63 and carry-out port 64 of the first load lock apparatus 21 and the carry-in port 103 and carry-out port 104 of the second load lock apparatus 22. In contrast, the above-described upper surface cooling plate 111 never presents such a disadvantage but allows the height between them to be smaller. This can accordingly decrease the range of the vertical movement of the carrier units 12 and 31 and enhance the efficiency of carrying the substrate G.

The lower surface cooling plate 112 forms a substantially rectangular thick plate, and is substantially horizontally provided along the bottom of the chamber 101, placed on the lower surface (for example, the rear surface on which no device is to be formed) side of the substrate G supported on the supporting members 110, and secured to the chamber 101. The above-described supporting members 110 are arranged within a plurality of holes 128 formed in the lower surface cooling plate 112 respectively. The lower surface cooling plate 112 is opposed to the lower surface of the substrate G supported on the holding members 110 in a position substantially parallel to the lower surface. Further, the substrate G and the lower surface cooling plate 112 are located close to each other, such that a clearance with a substantially uniform width is formed between the substrate G and the lower surface cooling plate 112. The upper surface of the lower surface cooling plate 112 has an area larger than that of the lower surface of the substrate G so that it can cool the lower surface of the substrate G supported on the supporting members 110 in a manner to cover the entire lower surface.

Further, a gas supply path 131 for supplying an inert gas such as N₂ (nitrogen) gas, He (helium) gas or the like into the load lock chamber 102 and an exhaust path 132 for forcibly evacuating the load lock chamber 102 are connected to the chamber 102. In other words, the gas supply from the gas supply path 131 and the forcible evacuation through the exhaust path 132 enable adjustment of the pressure in the load lock chamber 102.

Next, a process of processing the substrate G in the processing system 1 configured as described above will be described. The cassette C housing a plurality of substrates G is first mounted on the mounting table 11 in the carry-in/out section 2 with its opening 16 directed to the carrier unit 12 side. The carrier arm 15 of the carrier unit 12 is then caused to enter the opening 16 to take one substrate G The carrier arm 15 holding the substrate G is moved to a position opposed to the front of the gate valve 25 of the first load lock apparatus 21 located at the lower tier in the load lock section 5.

On the other hand, in the load lock section 5, the carry-in port 63 and the carry-out port 64 of the first load lock apparatus 21 are hermetically closed by the gate valves 25 and 26 in the closed state respectively so that the load lock chamber 62 is hermetically closed. The carry-in port 103 and the carry-out port 104 of the second load lock apparatus 22 are hermetically closed by the gate valves 27 and 28 in the closed state respectively so that the load lock chamber 102 is hermetically closed. Accordingly, the atmosphere in the carry-in/out section 2 and the atmosphere in the carrier room 33 in the processing section 3 are shut off from each other via the load lock section 5 (the load lock apparatuses 21 and 22). The atmosphere in the carry-in/out section 2 is, for example, at the atmospheric pressure, though the carrier room 33 is evacuated by exhausting air therein through the exhaust path 36. The carrier room 33 can be maintained in a substantially vacuum state because it is hermetically closed by the gate valves 27, 28, and 35.

In the first load lock apparatus 21, the pressure in the first load lock apparatus 21 is maintained at a predetermined pressure, that is, the substantially atmospheric pressure almost equal to that in the carry-in/out section 2, and the carry-in port 63 is then opened by opening the gate valve 25 with the carry-out port 64 kept closed by the gate valve 26. This makes the load lock chamber 62 communicate with the atmosphere in the carry-in/out section 2 via the carry-in port 63. Even during the carry-in port 63 kept open, the vacuum state in the carrier room 33 can be maintained by keeping the carry-out port 64 closed by the gate valve 26. Further, the lower surface heating plate 72 is lowered by driving of the cylinder 75 and kept waiting at the waiting position P1 in advance. After the carry-in port 63 is opened and the lower surface heating plate 72 is located at the waiting position P1 in this manner, the carrier arm 15 holding the substrate G is moved in the Y-axis direction to enter the load lock chamber 62 via the gate valve 25 and the carry-in port 63 and insert the substrate G between the upper surface heating plate 71 and the lower surface heating plate 72, so that the substrate G is passed from the carrier arm 15 onto the holding members 70. Since the lower surface heating plate 72 is lowered, a sufficient space is formed between the upper surface heating plate 71 and the lower surface heating plate 72, thus allowing the carrier arm 15 to easily pass the substrate G onto the holding members 70 without touching the lower surface heating plate 72 and the upper surface heating plate 71.

After the substrate G is carried in via the gate valve 25 and the carry-in port 63 and housed between the upper surface heating plate 71 and the lower surface heating plate 72 in this manner, and the carrier arm 15 retracts from the load lock chamber 62, the gate valve 25 is closed to bring the load lock chamber 62 into a hermetically closed state, and then the load lock chamber 62 is forcibly evacuated through the exhaust path 86, whereby the pressure in the load lock chamber 62 is reduced to a predetermined pressure for a vacuum state, that is, almost equal to the pressure in the carrier room 33. Note that the pressure in the load lock chamber 62 may be reduced while the inert gas is being supplied from the gas supply path 85 into the load lock chamber 62, that is, while the load lock chamber 62 is being purged using the inert gas, in which case the heating of the substrate G can be accelerated.

On the other hand, the substrate G housed between the upper surface heating plate 71 and the lower surface heating plate 72 is heated by the upper surface heating plate 71 and the lower surface heating plate 72. The lower surface heating plate 72 is first raised from the waiting position P1 by driving of the cylinder 75. Then, at a midpoint of raising of the lower surface heating plate 72, the substrate G is lifted by the supporting members 78 from the holding members 70 and kept supported on the supporting members 78. The substrate G supported on the supporting members 78 is raised integrally with the lower surface heating plate 72 and is brought close to the upper surface heating plate 71. Thus, in a state where the lower surface heating plate 72 is located at the heating processing position P2 so that the upper surface heating plate 71 is brought close to the entire upper surface of the substrate G, and the lower surface heating plate 72 is brought close to the entire lower surface of the substrate G, the substrate G is then heated by the upper surface heating plate 71 and the lower surface heating plate 72. By heating the substrate G from both surfaces, the substrate G can be uniformly heated and can be also efficiently heated in a short time. It should be noted that if the heating plate is brought close only to one surface of the substrate G to heat the substrate G only from the one surface, there will occur a temperature difference between the surface on the side to be heated and the surface on the opposite side, which difference may present a concern that the thermal stress causes deformation of the substrate G at the outer peripheral side in a direction away from the heating plate so that the substrate G gets warped. In contrast, uniformly heating the substrate G from both the surfaces by the upper surface heating plate 71 and the lower surface heating plate 72 can prevent occurrence of the temperature difference in the substrate G. Accordingly, warpage of the substrate G can be prevented.

Note that the heating of the substrate G in the load lock chamber 62 is preferably performed in parallel with the pressure reduction in the load lock chamber 62. This can reduce the processing time in the load lock chamber 62, resulting in efficient processing.

After the load lock chamber 62 is brought into an almost vacuum state, and the heating of the substrate G is finished, the carry-out port 64 is opened by opening the gate valve 26 with the carry-in port 63 kept closed by the gate valve 25. This makes the load lock chamber 62 communicate with the atmosphere in the carrier room 33 via the carry-out port 64. Even during the carry-out port 64 kept open, the vacuum state in the load lock chamber 62 and the carrier room 33 can be maintained by keeping the carry-in port 63 closed by the gate valve 25.

Further, the lower surface heating plate 72 is lowered from the heating processing position P2 and returned to the waiting position P1. Then, at a midpoint of lowering of the lower surface heating plate 72, the holding members 70 butts against the lower surface of the substrate G so that the substrate G is passed from the supporting members 78 onto the holding members 70. This separates the substrate G from the upper surface heating plate 71 and the lower surface heating plate 72 and brings the substrate G into a state supported on the holding members 70.

After the carry-out port 64 is opened and the lower surface heating plate 72 is located at the waiting position P1 as described above, the carrier arm 51 of the second carrier unit 31 is moved in the Y-axis direction and enters the load lock chamber 62 via the gate valve 26 and the carry-out port 64. The carrier arm 51 then receives the substrate G from the holding members 70, and the carrier arm 51 holding the substrate G retracts from the load lock chamber 62. Since the upper surface heating plate 71 is raised, sufficient spaces are formed between the upper surface heating plate 71 and the substrate G and between the lower surface heating plate 72 and the substrate G, thus allowing the carrier arm 51 to easily carry the substrate G out of the load lock chamber 62 without touching the upper surface heating plate 71 and the lower surface heating plate 72. Thus, the substrate G is carried out of the load lock chamber 62 via the carry-out port 64 and the gate valve 26 and carried into the carrier room 33 in the processing section 3.

In the processing chamber 3, the substrate G carried into the carrier room 33 is carried by the carrier arm 51 from the carrier room 33 into any of the substrate processing apparatuses 30A to 30E where the substrate G is subjected to film formation by the predetermined plasma CVD processing. In the one of the substrate processing apparatuses 30A to 30E, the substrate G is heated in a reduced pressure atmosphere, and a reaction gas is supplied into the processing chamber and made into plasma by energy of microwave. This forms a predetermined thin film on the front surface of the substrate G. Since the carried-in substrate G has been pre-heated in the load lock chamber 62, the heating time of the substrate G in the one of the substrate processing apparatuses 30A to 30E can be reduced, resulting in efficient processing.

After completion of the processing of the substrate G in the one of the substrate processing apparatuses 30A to 30E, the carrier arm 51 takes the substrate G out of the one of the substrate processing apparatuses 30A to 30E and carried it out to the carrier room 33. At this time, the substrate G is at a high temperature.

On the other hand, in the load lock section 5, the carry-in port 103 and the carry-out port 104 of the second load lock apparatus 22 are hermetically sealed by the gate valves 27 and 28 in the closed state so that the load lock chamber 102 is kept hermetically closed. Further, the load lock chamber 102 is forcibly evacuated through the exhaust path 132, so that the pressure in the load lock chamber 102 is reduced to a predetermined pressure for a vacuum state, that is, almost equal to the pressure in the carrier room 33 in advance. In this state, the carry-in port 103 is opened by opening the gate valve 27 with the carry-out port 104 kept closed by the gate valve 28. This makes the load lock chamber 102 communicate with the atmosphere in the carrier room 33 via the carry-in port 103. Even during the carry-in port 103 kept open, the vacuum state in the load lock chamber 102 and the carrier room 33 can be maintained by keeping the carry-out port 104 closed by the gate valve 28. Further, the upper surface cooling plate 111 is raised by driving of the cylinder 125 and kept waiting at the waiting position P3 in advance.

After the carry-in port 103 is opened and the upper surface cooling plate 111 is located at the waiting position P3, the carrier arm 51 holding the substrate G is moved in the Y-axis direction to enter the load lock chamber 102 via the gate valve 27 and the carry-in port 103, and enter between the upper surface cooling plate 111 and the lower surface cooling plate 112. The substrate G is then passed from the carrier arm 51 onto the supporting members 110. Since the upper surface cooling plate 111 is raised, a sufficient space is formed between the lower surface cooling plate 112 and the upper surface cooling plate 111, thus allowing the carrier arm 51 to easily pass the substrate G onto the supporting members 110 without touching the lower surface cooling plate 112.

After the substrate G at a high temperature carried out of the one of the substrate processing apparatuses 30A to 30E is carried in via the gate valve 27 and the carry-in port 103 and housed between the upper surface cooling plate 111 and the lower surface cooling plate 112 in this manner, and the carrier arm 51 retracts from the load lock chamber 102, the gate valve 27 is closed to bring the load lock chamber 102 into a hermetically closed state. The inert gas is then supplied from the gas supply path 131 into the load lock chamber 102 to increase the pressure in the load lock chamber 102 until the pressure in the second load lock apparatus 22 is brought to a predetermined pressure, that is, a substantially atmospheric pressure almost equal to the pressure in the carry-in/out section 2.

On the other hand, the substrate G is cooled by the upper surface cooling plate 111 and the lower surface cooling plate 112. At the time of cooling, driving of the cylinder 125 lowers the upper surface cooling plate 111 to the cooling processing position P4 so as to bring it close to the upper surface of the substrate G. More specifically, in a state where the upper surface cooling plate 111 is brought close to the entire upper surface of the substrate G and the lower surface cooling plate 112 is brought close to the entire lower surface such that clearances with respective substantially uniform widths are formed between the upper surface cooling plate 111 and the substrate G and between the lower surface cooling plate 112 and the substrate G, the substrate G is uniformly cooled by the upper surface cooling plate 111 and the lower surface cooling plate 112. By cooling the substrate G from both surfaces, the substrate G can be uniformly cooled and can be also efficiently cooled in a short time. It should be noted that if the cooling plate is brought close only to one surface of the substrate G to cool the substrate G only from the one surface, there will occur a temperature difference between the surface on the side to be cooled and the surface on the opposite side, which difference may present a concern that the thermal stress causes deformation of the substrate G at the outer peripheral side in a direction close to the cooling plate so that the substrate G gets warped. In contrast, uniformly cooling the substrate G from both the surfaces by the upper surface cooling plate 111 and the lower surface cooling plate 112 can prevent occurrence of the temperature difference in the substrate G. Accordingly, warpage of the substrate G can be prevented.

Note that the cooling of the substrate G in the load lock chamber 102 is preferably performed in parallel with the pressurization of the load lock chamber 102. This can reduce the processing time in the load lock chamber 102, resulting in efficient processing. Further, a cold blast of the inert gas supplied from the gas supply path 131 may be used to accelerate the cooling of the substrate G.

After the load lock chamber 102 is brought into a substantially atmospheric state, and the cooling of the substrate G is finished, the carry-out port 104 is opened by opening the gate valve 28 with the carry-in port 103 kept closed by the gate valve 27. This makes the load lock chamber 102 communicate with the atmosphere in the carry-in/out section 2 via the carry-out port 104. Even during the carry-out port 104 kept open, the vacuum state in the carrier room 33 can be maintained by keeping the carry-in port 103 closed by the gate valve 27. The upper surface cooling plate 111 is raised from the cooling processing position P4 and returned to the waiting position P3.

After the carry-out port 104 is opened and the upper surface cooling plate 111 is located at the waiting position P3, the carrier arm 15 of the carrier unit 12 is moved in the Y-axis direction and enter the load lock chamber 102 via the gate valve 28 and the carry-out port 104. The carrier arm 15 then receives the substrate G from the supporting members 110, and the carrier arm 15 holding the substrate G retracts from the load lock chamber 102. Since the upper surface cooling plate 111 is raised, a sufficient space is formed between the upper surface cooling plate 111 and the lower surface cooling plate 112, thus allowing the carrier arm 15 to easily carry the substrate G out of the load lock chamber 102 without touching the upper surface cooling plate 111 and the lower surface cooling plate 112.

Thus, the substrate G is carried out of the load lock chamber 102 via the carry-out port 104 and the gate valve 28 and carried into the carry-in/out section 2. The substrate G is then returned by the carrier arm 15 to the cassette C on the mounting table 11. In the above manner, a series of processing processes in the processing system 1 is finished.

It should be noted that, in the above-described series of processes, after the substrate G is carried out of the load lock chamber 62 in the first load lock apparatus 21 to the carrier room 33, the gate valve 26 closes the carry-out port 64 to keep the load lock chamber 62 in a hermetically closed state again, and supply of the inert gas from the gas supply path 85 is started to return the load lock chamber 62 to the substantially atmospheric atmosphere. While the substrate G is carried to one of the substrate processing apparatuses 30A to 30E and subjected to CVD processing, a next unprocessed substrate G can be carried into the load lock chamber 62, the pressure in the load lock chamber 62 can be reduced, and the substrate G can be pre-heated. More specifically, it is possible to continuously perform the reduction in the pressure and the pre-heating in the first load lock apparatus 21, and sequentially carry the substrates G from the load lock chamber 62 into the substrate processing apparatuses 30A to 30E, so as to perform the CVD processing for up to five substrates G in parallel. Further, after the substrate G is carried out of the load lock chamber 102 of the second load lock apparatus 22 to the carry-in/out section 2, the gate valve 28 closes the carry-out port 104 to keep the load lock chamber 102 in a hermetically closed state, and forcible evacuation is performed through the exhaust path 132 to return the load lock chamber 102 to the vacuum state. Then, the next processed substrate G is carried out of one of the substrate processing apparatuses 30A to 30E into the load lock chamber 102, and the pressurization of the load lock chamber 102 and the cooling of the substrate G can be performed. More specifically, it is possible to sequentially carry the processed substrates G from the substrate processing apparatuses 30A to 30E to the load lock chamber 102, continuously perform the pressurization and the cooling in the second load lock apparatus 22, and consecutively return the substrates G to the carry-in/out section 2. Then, immediately after the substrates G are carried out of the substrate processing apparatuses 30A to 30E, unprocessed substrates G are sequentially carried from the load lock chamber 62 into the substrate processing apparatuses 30A to 30E, so that the CVD processing is continuously performed. Thus, it is possible to perform in parallel the pressure-reduction and the pre-heating in the first load lock apparatus 21, the CVD processing in the substrate processing apparatuses 30A to 30E, and the pressurization and the cooling in the second load lock apparatus 22, thereby continuously operating the first load lock apparatus 21, the substrate processing apparatuses 30A to 30E, and the second load lock apparatus 22 without keeping them waiting for a long time, so that the plurality of substrates G can be efficiently processed.

According to the processing system 1, the heating the substrate G from both surfaces by the upper surface heating plate 71 and the lower surface heating plate 72 can efficiently heat the substrate G in the first load lock apparatus 21. Such heating makes it possible to reduce the time of heating the substrate G in the first load lock apparatus 21 to thereby efficiently supply the substrates G to the substrate processing apparatuses 30A to 30E without keeping the substrate processing apparatuses 30A to 30E for a long time. In other words, the efficiency of heating the substrate G can be increased to improve the throughput. Further, since the heating the substrate from both surfaces suppresses the temperature difference between both surfaces of the substrate G, the warped deformation of the substrate G can be prevented. Accordingly, it is possible to prevent occurrence of breakage in the substrate G and a state of the substrate G unstably held by the carrier arm 51 at the time of carriage, and to heat preferably and uniformly the substrate G, resulting in excellent CVD processing performed for the substrates G in the substrate processing apparatuses 30A to 30E.

Further, the cooling the substrate G from both surfaces by the upper surface cooling plate 111 and the lower surface cooling plate 112 can efficiently cool the substrate G in the second load lock apparatus 22. Such cooling makes it possible to reduce the time of cooling the substrate G in the second load lock apparatus 22 to thereby efficiently carry out the substrate G to the carry-in/out section 2, and therefore it is possible to efficiently carry the substrates G for which processing has been finished in the substrate processing apparatuses 30A to 30E to the second load lock apparatus 22 and carry the substrates G out to the carry-in/out section 2 without keeping the substrates G waiting for a long time. In other words, the efficiency of cooling the substrate G can be increased to improve the throughput. Further, since the cooling the substrate from both surfaces suppresses the temperature difference between both surfaces of the substrate G, the warped deformation of the substrate G can be prevented. Accordingly, it is possible to prevent occurrence of breakage in the substrate G and a state of the substrate G unstably held by the carrier arm 15 at the time of carriage, and to securely house the substrate G in the cassette C.

A preferred embodiment of the present invention has been described above, but the present invention is not limited to the embodiment. It should be understood that various changes and modifications are readily apparent to those skilled in the art within the scope of the technical spirit as set forth in claims, and those should also be covered by the technical scope of the present invention.

Although one first load lock apparatus 21 for heating is provided in the above-described embodiment, two or more first load lock apparatuses 21 may be provided. Further, although one second load lock apparatus 22 for cooling is provided, two or more second load lock apparatuses 22 may be provided. Further, the first load lock apparatus 21 for heating and the second load lock apparatuses 22 for cooling are not limited to those stacked one on the other, but they may be laterally arranged, for example, side by side, or may be provided at positions away from each other.

Although in the first load lock apparatus 21, the lower surface heating plate 72 is configured such that it can be raised and lowered with respect to the chamber 61 and receive the substrate G from the holding members 70 through use of the supporting members 78 on the lower surface heating plate 72, the lower surface heating plate 72 may be configured not to receive the substrate G but to be only brought close to the substrate G supported on the holding members 70 (in this case, serving as the supporting members for supporting the substrate at time of heating). Further, the upper surface heating plate 71 may be configured such that it can be raised and lowered with respect to the chamber 61, so that movement of raising and lowering of the upper surface heating plate 71 itself can bring the upper surface heating plate 71 close to and away from the substrate G Further, although the upper surface heating plate 71 and the lower surface heating plate 72 are configured to heat the substrate G with the plates 71 and 72 kept close to the substrate G with clearances intervening between the plates 71 and 72 and the substrate G respectively in the above-described embodiment, the upper surface heating plate 71 and the lower surface heating plate 72 may heat the substrate G with the plate 71 or 72 keeping in touch with the substrate G.

Although in the second load lock apparatus 22, the upper surface cooling plate 111 is configured such that it can be raised and lowered with respect to the chamber 101 so as to be brought close to or away from the substrate G and the lower surface cooling pate 112 is secured to the chamber 111, the lower surface cooling pate 112 may be configured, as a matter of course, such that it can also be brought close to or away from the substrate G Further, the lower surface cooling plate 112 may be configured such that supporting members for supporting the substrate G are provided on the upper surface of the lower surface cooling plate 112, for example, similarly to the lower surface heating plate 72 in the first load lock apparatus 21, to receive the substrate G from the supporting members 110 at the time of cooling the substrate G In this case, the upper surface cooling plate 111 and the lower surface cooling plate 112 can be configured such that they can be relatively brought close to and away from the substrate G housed between them respectively. Further, although the upper surface cooling plate 111 and the lower surface cooling plate 112 are configured to cool the substrate G with the plates 111 and 112 kept close to the substrate G with clearances intervening between the plates 111 and 112 and the substrate G respectively in the above embodiment, the upper surface cooling plate 111 and the lower surface cooling plate 112 may cool the substrate G with the plates 111 and 112 keeping in touch with the substrate G.

The processing system is not limited to the multi-chamber type including a plurality of substrate processing apparatuses. The number of substrate processing apparatuses included in the processing section may be one. Although the processing system 1 in which the plasma CVD processing is performed in the processing section 3 has been described in the above embodiment, the processing performed in the processing section may be other processing. The present invention is also applicable to a processing system performing, in the processing section, other processing performed in a reduced-pressure atmosphere, for example, thermal CVD processing, etching processing, ashing processing, and so on. Further, although the case in which the substrate G for LCD is processed has been described in the above embodiment, the substrate may be other one, for example, a semiconductor wafer or the like.

The present invention is applicable, for example, to a processing system for performing a CVD processing of a substrate, a load lock apparatus included in the processing system, and a processing method in the processing system.

According to the present invention, heating the substrate from both surfaces by a first heating plate and a second heating plate enables efficient heating of the substrate and suppression of a temperature difference between both surfaces to prevent deformation of the substrate. Further, cooling the substrate from both surfaces by a first cooling plate and a second cooling plate enables efficient cooling of the substrate and suppression of a temperature difference between both surfaces to prevent deformation of the substrate. The heating and cooling efficiencies of the substrate can be increased to improve the throughput.

What is claimed is:

1. A load lock apparatus including a carry-in port provided on a side of a carry-in/out section for carrying in/out a substrate, a carry-out port provided on a side of a processing section for processing the substrate, and supporting members for supporting the substrate, said apparatus comprising:
a first heating plate and a second heating plate each for heating the substrate supported on said supporting members,
wherein one of said first heating plate and said second heating plate is located on a front surface side of the substrate and another is located on a rear surface side of the substrate.

2. The load lock apparatus as set forth in claim 1,
wherein the substrate is substantially horizontally supported on said supporting members.

3. The load lock apparatus as set forth in claim 1,
wherein said first heating plate and/or said second heating plate are/is capable of being relatively brought close to or away from the substrate.

4. A load lock apparatus including a carry-out port provided on a side of a carry-in/out section for carrying in/out a substrate, a carry-in port provided on a side of a processing section for processing the substrate, and supporting members for supporting the substrate, said apparatus comprising:
a first cooling plate and a second cooling plate each for cooling the substrate supported on said supporting members,
wherein one of said first cooling plate and said second cooling plate is located on a front surface side of the substrate and another is located on a rear surface side of the substrate.

5. The load lock apparatus as set forth in claim 4,
wherein the substrate is substantially horizontally supported on said supporting members.

6. The load lock apparatus as set forth in claim 4,
wherein said first cooling plate and/or said second cooling plate are/is capable of being relatively brought close to or away from the substrate.

7. A load lock section comprising a first load lock apparatus including a carry-in port provided on a side of a carry-in/out section for carrying in/out a substrate, a carry-out port provided on a side of a processing section for processing the substrate, and supporting members for supporting the substrate; and a second load lock apparatus including a carry-out port provided on the carry-in/out section side, a carry-in port provided on the processing section side, and supporting members for supporting the substrate,
wherein said first load lock apparatus comprises a first heating plate and a second heating plate each for heating the substrate supported on said supporting members,
wherein one of said first heating plate and said second heating plate is located on a front surface side of the substrate and another is located on a rear surface side of the substrate,
wherein said second load lock apparatus comprises a first cooling plate and a second cooling plate each for cooling the substrate supported on said supporting members, and
wherein one of said first cooling plate and said second cooling plate is located on the front surface side of the substrate and another is located on the rear surface side of the substrate.

8. The load lock section as set forth in claim 7,
wherein said first load lock apparatus and said second load lock apparatus are stacked one on the other.

9. A substrate processing system comprising a processing section for processing a substrate; a carry-in/out section for carrying in/out the substrate; and a load lock section provided between said processing section and said carry-in/out section,
wherein said load lock section comprises a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate,
wherein said first load lock apparatus comprises a first heating plate and a second heating plate each for heating the substrate supported on said supporting members,
wherein one of said first heating plate and said second heating plate is located on a front surface side of the substrate and another is located on a rear surface side of the substrate, and
wherein said processing section comprises a carrier unit for carrying the substrate between a substrate processing apparatus for processing the substrate and said load lock section.

10. A substrate processing system comprising a processing section for processing a substrate; a carry-in/out section for carrying in/out the substrate; and a load lock section provided between said processing section and said carry-in/out section,
wherein said load lock section comprises a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate,
wherein said second load lock apparatus comprises a first cooling plate and a second cooling plate each for cooling the substrate supported on said supporting members,
wherein one of said first cooling plate and said second cooling plate is located on a front surface side of the substrate and another is located on a rear surface side of the substrate, and
wherein said processing section comprises a carrier unit for carrying the substrate between a substrate processing apparatus for processing the substrate and said load lock section.

11. A substrate processing system comprising a processing section for processing a substrate; a carry-in/out section for carrying in/out the substrate; and a load lock section provided between said processing section and said carry-in/out section,
wherein said load lock section comprises a first load lock apparatus including a carry-in port provided on a side of the carry-in/out section for carrying in/out the substrate, a carry-out port provided on a side of the processing section for processing the substrate, and supporting members for supporting the substrate; and a second load lock apparatus including a carry-out port provided on the carry-in/out section side, a carry-in port provided on the processing section side, and supporting members for supporting the substrate,
wherein said first load lock apparatus comprises a first heating plate and a second heating plate each for heating the substrate supported on said supporting members,
wherein one of said first heating plate and said second heating plate is located on a front surface side of the substrate and another is located on a rear surface side of the substrate,
wherein said second load lock apparatus comprises a first cooling plate and a second heating plate each for cooling the substrate supported on said supporting members,
wherein one of said first cooling plate and said second cooling plate is located on the front surface side of the substrate and another is located on the rear surface side of the substrate, and
wherein said processing section comprises a carrier unit for carrying the substrate between a substrate processing apparatus for processing the substrate and said load lock section.

12. A substrate processing method of carrying a substrate from a carry-in/out section into a processing section via a first load lock apparatus provided in a load lock section, processing the substrate in the processing section, and carrying the substrate out of the processing section into the carry-in/out section via a second load lock apparatus provided in the load lock section, said method comprising the steps of:
opening a carry-in port provided on the carry in/our section side of the first load lock apparatus with a carry-out port provided on the processing section side of the first load lock apparatus kept closed;
carrying the substrate into the first load lock apparatus via the carry-in port of the first load lock apparatus, housing the substrate between a first heating plate and a second heating plate provided in the first load lock apparatus, and closing the carry-in port of the first load lock apparatus;
heating the substrate housed in the first load lock apparatus from both surfaces by the first heating plate and the second heating plate; and
opening the carry-out port of the first load lock apparatus with the carry-in port of the first load lock apparatus kept closed, and carrying the substrate into the processing section via the carry-out port of the first load lock apparatus.

13. The processing method as set forth in claim 12,
wherein a pressure in the processing section is reduced below a pressure in the carry-in/out section,
wherein after the substrate is carried into the first load lock apparatus, the carry-in port of the first load lock apparatus is closed to bring an inside of the first load lock apparatus into a hermetically closed state; and
wherein a pressure in the first load lock apparatus is reduced to a predetermined pressure, and the carry-out port of the first load lock apparatus is then opened to carry the substrate out of the first load lock apparatus to the processing section.

14. The processing method as set forth in claim 12, further comprising the steps of:
opening a carry-in port provided on the processing section side of the second load lock apparatus with a carry-out port provided on the carry-in/out section side of the second load lock apparatus kept closed;
carrying the substrate into the second load lock apparatus via the carry-in port of the second load lock apparatus, housing the substrate between a first cooling plate and a second cooling plate provided in the second load lock apparatus, and closing the carry-in port of the second load lock apparatus;
cooling the substrate housed in the second load lock apparatus from both surfaces by the first cooling plate and the second cooling plate; and
opening the carry-out port of the second load lock apparatus with the carry-in port of the second load lock apparatus kept closed, and carrying out the substrate to the carry-in/out section via the carry-out port of the second load lock apparatus.

15. The processing method as set forth in claim 14,
wherein a pressure in the processing section is reduced below a pressure in the carry-in/out section,
wherein after the substrate is carried into the second load lock apparatus, the carry-in port of the second load lock apparatus is closed to bring an inside of the second load lock apparatus into a hermetically closed state, and
wherein a pressure in the second load lock apparatus is increased to a predetermined pressure, and the carry-out port of the second load lock apparatus is then opened to carry the substrate out of the second load lock apparatus to the carry-in/out section.

16. A substrate processing method of carrying a substrate from a carry-in/out section into a processing section via a first load lock apparatus provided in a load lock section, processing the substrate in the processing section, and carrying the substrate out of the processing section into the carry-in/out section via a second load lock apparatus provided in the load lock section, said method comprising the steps of:
at the time of carrying the substrate from the processing section to the carry-in/out section, opening a carry-in port provided on the processing section side of the second load lock apparatus with a carry-out port provided on the carry-in/out section side of the second load lock apparatus kept closed;
carrying the substrate into the second load lock apparatus via the carry-in port of the second load lock apparatus, housing the substrate between a first cooling plate and a second cooling plate provided in the second load lock apparatus, and closing the carry-in port of the second load lock apparatus;
cooling the substrate housed in the second load lock apparatus from both surfaces by the first cooling plate and the second cooling plate; and
opening the carry-out port of the second load lock apparatus with the carry-in port of the second load lock apparatus kept closed, and carrying out the substrate to the carry-in/out section via the carry-out port of the second load lock apparatus.

17. The processing method as set forth in claim 16,
wherein a pressure in the processing section is reduced below a pressure in the carry-in/out section,
wherein after the substrate is carried into the second load lock apparatus, the carry-in port of the second load lock apparatus is closed to bring an inside of the second load lock apparatus into a hermetically closed state; and
wherein a pressure in the second load lock apparatus is increased to a predetermined pressure, and the carry-out port of the second load lock apparatus is then opened to carry the substrate out of the second load lock apparatus to the carry-in/out section.
